(19) United States
(12) Patent Application Publication
(10) Pub. No.: US 2014/0216812 A1
(43) Pub. Date: Aug. 7, 2014

(54) WIRE HARNESS WITH PROTECTIVE MEMBER

(71) Applicant: Yazaki Corporation, Tokyo (JP)

(72) Inventors: Hideomi ADACHI, Kosai-shi (JP); Yoshiaki OZAKI, Kosai-shi (JP)

(73) Assignee: YAZAKI CORPORATION, Tokyo (JP)

(21) Appl. No.: 14/247,780

(22) Filed: Apr. 8, 2014

Related U.S. Application Data
(63) Continuation of application No. PCT/JP2012/078410, filed on Oct. 26, 2012.

(30) Foreign Application Priority Data
Oct. 31, 2011 (JP) 2011-238851

(51) Int. Cl. H05K 9/00; B60R 16/02; H02G 3/04

(52) U.S. Cl. CPC H05K 9/00; H02G 3/04; B60R 16/0207
USPC 174/72 A

(57) ABSTRACT

A wire harness includes one or more conducting paths, a protective member that is formed in a pipe shape, and accommodates the one or more conducting paths in the protective member to shield a electromagnetic wave emitted from the one or more conducting paths. The protective member is formed of resin composition that has conductivity.

### CROSS REFERENCE TO RELATED APPLICATIONS

This application is a continuation of PCT application No. PCT/JP2012/078410, which was filed on Oct. 26, 2012 based on Japanese Patent Application (No. 2011-238851) filed on Oct. 31, 2011, the contents of which are incorporated herein by reference.

### BACKGROUND OF THE INVENTION

1. Field of the Invention

The present invention relates to a wire harness.

2. Description of the Related Art

A high voltage wire harness is used to electrically connect devices of a hybrid vehicle or an electric vehicle, namely, devices such as a motor unit, an inverter unit or a battery.

A wire harness disclosed in Japanese Patent No. 3909763 includes three electric wires which are electrically connected between devices, a main shielding part which accommodates the three electric wires for most of their full length, and sub shielding parts which extend from the ends of the main shielding part and cover the three electric wires. It is possible that the wiring course of the wire harness becomes very long depending on the mounted position of the device.

Each end of the three electric wires is provided with a terminal fitting. The terminal fitting is adapted to be inserted into a shield housing of the device together with the ends of the electric wires, and connected with, for example, bolting to a connecting part disposed at a predetermined position of the device body after the manufacture of the wire harness.

A long metal pipe that has conductivity is used as the main shielding part. To reduce the diameter of the main shielding part, the main shielding part is formed to have such an inside diameter that only the three electric wires can be inserted through.

The sub shielding part includes a braid which is formed into a pipe shape, a shield shell which is fixed to one end of the braid and a connecting pipe which is fixed to the other end of the braid. The shield shell is included as a part to be connected and fixed to the shield housing of the device.

The braid and the shield shell are fixed by making the braid and the shield shell to be overlapped, placing a shield ring on the overlapped part, and then performing a crimping on the shield ring. The above fixing method is also adopted in the fixation of the braid and the connecting pipe. In other words, the braid and the connecting pipe are fixed by making the braid and the connecting pipe to be overlapped, placing a crimp ring on the overlapped part, and then performing a crimping on the crimp ring.

A metal pipe of the same material and the same inside diameter as the main shielding part is used as the connecting pipe. The connecting pipe has such a length that is remarkably shorter than that of the main shielding part. The connecting pipe is fixed with welding upon making the end of the connecting pipe align with the end of the main shielding part.

It is found in the above construction and structure that, as described above, because the sub shielding part is integrally welded with the main shielding part, the wire harness includes a shielding member formed of a very long metal pipe.

### SUMMARY OF THE INVENTION

However, in the above wire harness, although an electromagnetic shielding effect is obtained as an electromagnetic wave measure by using the metal pipe, there is a following problem. That is, because the wire harness includes the shielding member formed of a very long metal pipe, the whole weight of the wire harness is increased. The above problem has an influence on the reduction of the weight of the vehicle.

The present invention is made in view of the above described circumstances, and an object of the present invention is to provide a wire harness so that while an electromagnetic shielding effect is ensured, the wire harness can be lighter in weight and the vehicle can be lighter in weight.

An aspect of the present invention provides a wire harness, including: one or more conducting paths; a protective member that is formed in a pipe shape, and accommodates the one or more conducting paths in the protective member to shield a electromagnetic wave emitted from the one or more conducting paths, wherein the protective member is formed of resin composition that has conductivity.

According to the wire harness having such configuration, the wire harnesses is provided with the pipe-like protective member which is formed of resin composition that has conductivity. Because the protective member is made of resin composition that has conductivity the protective member can be lighter in weight than a metal pipe. Further, because the protective member has conductivity, an electromagnetic shielding effect can be also secured.

The wire harness may be configured by further including an insulating resin coating that is formed of resin composition having a property of insulating, wherein an outside surface of the protective member is covered with the insulating resin coating.

According to the wire harness having such configuration, because the outside surface of the protective member is covered with the insulating resin coating, while the wire harness is protected from an external force such as an impact, the wiring path of the wire harness can be regulated by the insulating resin coating without providing, for example, an exterior member such as a protector outside the protective member.

The wire harness may be configured so that an outside surface of an end part of the protective member is exposed for a predetermined range, and the exposed part is formed as a shielding member connecting part to be connected to a shield member.

According to the wire harness having such configuration, because the outside surface of the end part of the protective member is exposed for a predetermined range and the exposed part is formed as the shielding member connecting part, the protective member has a portion which protects the wire harness from an external force such as an impact, and portions which connect with the shielding members such as the braids.

The wire harness may be configured by further including a braid that is connected and fixed to an end part of the protective member.

The wire harness may be configured so that the braid is connected and fixed to each of both ends of the protective member, and the protective member is extended along an entire length between the both ends connected and fixed to the braids.

According to the aspect of the invention, because the wire harness is provided with the protective member formed of resin composition that has conductivity, an effect is achieved that while an electromagnetic shielding effect is secured, the wire harness can be lighter in weight and the vehicle can be lighter in weight.

According to the further configuration of the wire harness, the following effects are also achieved. In other words, because the outside surface of the protective member is covered with the insulating resin coating, an effect is achieved that a protection function in the wire harness can be improved. Further, because the wiring path of the wire harness can be regulated by the insulating resin coating, since it is not necessary to provide an exterior member such as a protector, an effect is achieved that the number of components related to the wiring path regulation of the wire harness and the operating man-hours related to the assembly of the exterior member can be reduced. An effect is achieved that the wire harness can be provided so that the manufacturing cost can be reduced and the operability can be improved.

According to the further configuration of the wire harness, the following effects are also achieved. In other words, because the protective member has a portion which protects the wire harness from an external force such as an impact, and portions which connect shielding members such as the braids, an effect is achieved that while a protection function is secured, the portions connecting to the shielding members at the end parts of the protective member can be secured.

### BRIEF DESCRIPTION OF THE DRAWINGS

FIG. 1 is a schematic diagram of a vehicle in which a wire harness according to an embodiment of the present invention is wired.

FIG. 2 is a cross-sectional view which shows a construction of a wire harness according to a first embodiment.

FIG. 3 is a cross-sectional view which shows a construction of a protective member according to the first embodiment.

FIG. 4 is a cross-sectional view which shows a construction of a wire harness according to a second embodiment.

FIG. 5 is a cross-sectional view which shows a construction of a protective member according to the second embodiment.

### DETAILED DESCRIPTION OF THE EXEMPLARY EMBODIMENTS

A wire harness includes a plurality of high voltage electric wires (conducting paths), a protective member which collectively covers and shields the plurality of high voltage electric wires, and terminal shielding members which are connected to two end part parts of the protective member.

### First Embodiment

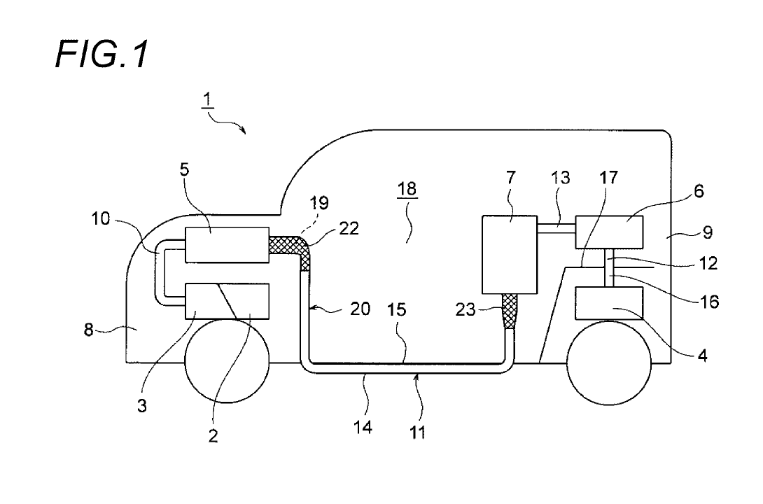

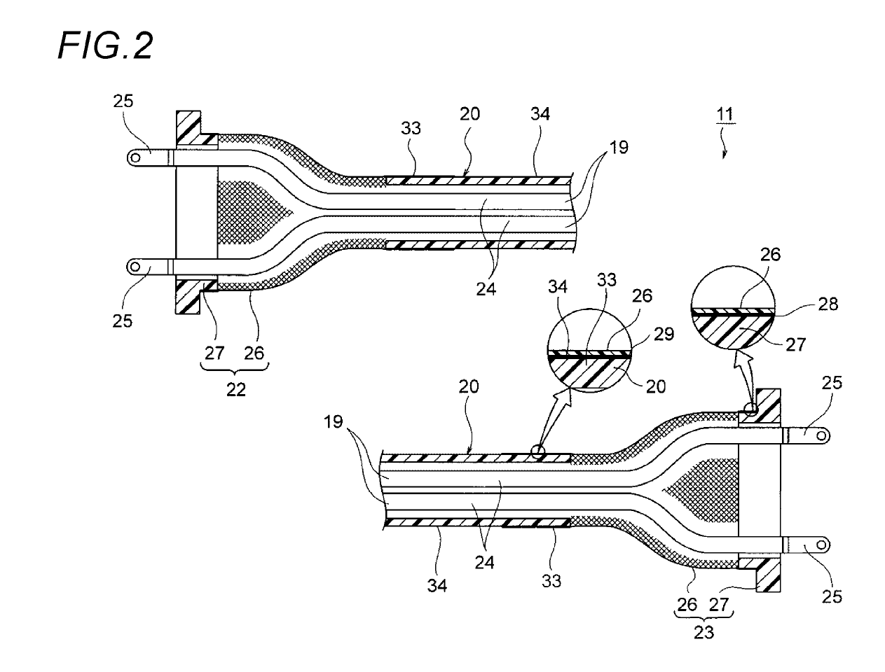

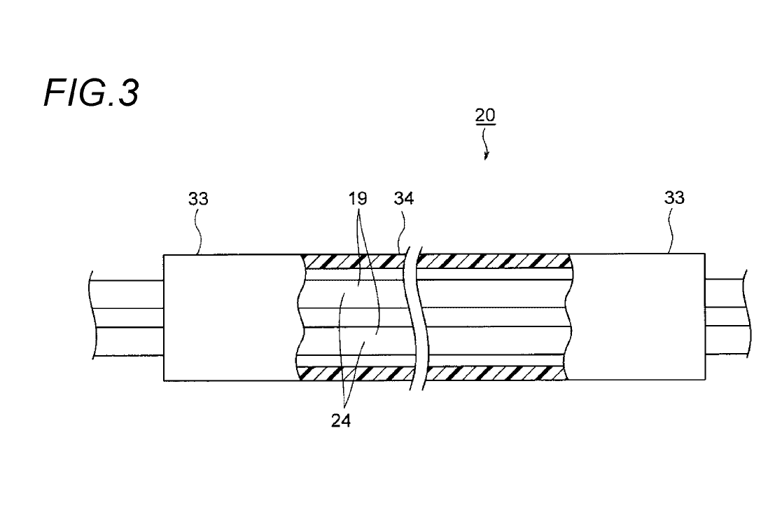

Next, a first embodiment is described with reference to the figures. FIG. 1 is a schematic diagram of a vehicle in which a wire harness according to the first embodiment of the present invention is wired. FIG. 2 is a cross-sectional view which shows a construction of the wire harness. FIG. 3 is a cross-sectional view which shows a construction of a protective member.

In the following description, specific shapes, materials, numerical values, directions and the like are illustrated to facilitate the understanding of the present invention and may be changed appropriately depending on applications, objects, specifications or the like.

In the first embodiment, an example in which a wire harness middle member and a wire harness is applied to a hybrid vehicle (it may be an electric vehicle) is given and described.

FIG. 1 shows a hybrid vehicle 1. The hybrid vehicle 1 is a vehicle which is driven by using an engine 2, a front motor unit 3 and a rear motor unit 4 together, and electric power from a battery 7 (battery pack or unit battery) is adapted to be supplied to the front motor unit 3 through a front inverter unit 5 and to the rear motor unit 4 through a rear inverter unit 6. The engine 2, the front motor unit 3 and the front inverter unit 5 are mounted in an engine room 8 at the position of front wheels and the like in the first embodiment. The rear motor unit 4, the rear inverter unit 6 and the battery 7 are mounted in a vehicle rear part 9 of rear wheels and the like. The mounted positions shall be an example. The position of the battery 7 shall not be particularly limited as long as the battery 7 can be used in the hybrid vehicle 1 or an electric vehicle.

The front motor unit 3 and the front inverter unit 5 are connected by a high voltage wire harness 10. The front inverter unit 5 and the battery 7 are also connected by a high voltage wire harness 11. The rear motor unit 4 and the rear inverter unit 6 are also connected by a high voltage wire harness 12. The rear inverter unit 6 and the battery 7 are also connected by a high voltage wire harness 13.

A middle part 14 of the wire harness 11 is wired at the ground side of a vehicle body floor 15. The wire harness 11 is wired generally in parallel with the vehicle body floor 15. The vehicle body floor 15 is a well-known body and is a so-called panel member, and through holes (reference numbers are omitted) are formed at predetermined positions. The through holes correspond to parts to which the wire harness 11 is inserted.

The wire harness 12 is wired so that a middle part 16 of the wire harness 12 penetrates through a vehicle body floor 17 in the vehicle rear part 9. A through hole into which the wire harness 12 is inserted is formed like the through holes of the wire harness 11. A reference number 18 indicates an indoor part.

Because the wire harness 10 is connected to the front motor unit 3 and because the wire harness 12 is connected to the rear motor unit 4, the wire harness 10 and the wire harness 12 may be called a motor cable or a motor cable device. In addition, because the wire harness 11 is wired under the vehicle body floor 15, the wire harness 11 may be called an underfloor wire harness.

The first embodiment of the present invention is described as follows by using the wire harness 11 as an example. The first embodiment can be applied to not only the wire harness 11, but also the wire harness 10, 12 and 13.

The wire harness 11 is intended to electrically connect the front inverter unit 5 to the battery 7 (refer to FIG. 1), and includes two high voltage electric wires 19 (or referred to as conducting paths), a protective member 20 which is also used as a shielding member to collectively cover and shield the two high voltage electric wires 19, and two flexible terminal shielding members 22 and 23, as shown in FIG. 2. The protective member 20 is a characteristic member in the first embodiment. The protective member 20 of the wire harness 11 is formed of a resin composition that has conductivity formed into a pipe shape. Because the protective member 20 is also used as a shielding member as described above, the protective member 20 corresponds to a member that plays a shielding function.

As described above, the protective member 20 is made of a resin composition that has conductivity. As shown in FIGS. 2 and 3, the protective member 20 is formed to have such a size (diameter) and such a length that a predetermined range of the two high voltage electric wires 19 can be covered with the protective member 20. In the first embodiment, the protective member 20 is molded by extruding a resin composition that has conductivity into a pipe shape of a circular cross section. What is formed by mixing a conductive material with a resin material is cited as the resin composition that has conductivity. In particular, what is formed by mixing carbon fiber with resin materials such as PBT (polybutylene terephthalate) is cited as an example. Because the protective member 20 is not made of metal, but is made of resin, the protective member 20 becomes lightweight.

The high voltage electric wire 19 is a high voltage conducting path including a conductor and an insulator (coating) 24, and is formed to have a length that is necessary for electrical connection. The conductor (not shown in the figure) is made of copper, copper alloy, aluminum or aluminum alloy. The conductor may be either a conductor structure in which strands are twisted or a rod-like conductor structure whose cross section is a rectangular shape or a round shape (for example, a conductor structure with a rectangular single core or a round single core, and in this case, the electric wire itself becomes rod-like).

The high voltage electric wires 19 are used in the present embodiment, but the invention shall not be limited to this. That is, it is also possible to provide an insulator to a well-known bus bar to be used as a high voltage conducting path.

A predetermined length of the insulator 24 at each end of the high voltage electric wire 19 is removed. From this removed portion, a conductor (not shown in the figure) is exposed. A terminal fitting 25 is connected to the exposed conductor (refer to FIG. 2). The terminal fitting 25 is provided as a part connected to a connecting part, which is not shown, of the front inverter unit 5, or as a part connected to a connecting part, which is not shown, of the battery 7.

In FIG. 1, one terminal shielding member 22 is provided as a connecting member to the front inverter unit 5, and the other terminal shielding member 23 is provided as a connecting member to the battery 7. While the terminal shielding member 22 is connected to one end of the protective member 20, the terminal shielding member 23 is connected to the other end of the protective member 20.

Each of the two terminal shielding members 22 and 23 includes a braid 26 and a shield shell 27 which is electrically connected to one end of the braid 26, as shown in FIG. 2. The shield shell 27 which forms the terminal shielding member 22 is formed to be connected and fixed to a shield housing of the front inverter unit 5. The shield shell 27 which forms the terminal shielding member 23 is formed to be connected and fixed to the battery 7.

The braid 26 is formed as a pipe-like electromagnetic shielding member (a shielding member for electromagnetic wave measures). The braid 26 is formed to have such a size that a predetermined range of the two high voltage electric wires 19 can be covered with the braid 26, as shown in FIG. 2. The braid 26 is formed by using a lot of extra-fine strands that have conductivity, and braiding these strands into a net-like shape.

The above strand may be an extra-fine strand including a metal strand such as an annealed copper strand, or a nonmetal fiber. The nonmetal fiber may be a conductive resin fiber in which conductive material is mixed with carbonaceous fiber or resin material. Other than these strands, for example, a resin strand (PET (polyethylene terephthalate) strand) may be mixed to possess abrasion resistance. In order to connect and fix the braid 26 in the embodiment to the end part 33 of the protective member 20 and the shield shell 27 to be described below with welding, the braid 26, which is formed by braiding conductive resin fiber into a net-like shape, is used. This is an example and the invention is not limited to this.

A conductive resin shield shell made of resin composition that has conductivity is used as the shield shell 27 in the embodiment, but, besides this, for example, a shield shell made of metal that has conductivity may be used. The connection and fixation of the braid 26 and the shield shell 27 may be performed by, for example, welding, adhering or soldering the connecting points of the braid 26 and the shield shell 27. As an example of the connection with the welding, the braid 26, which is formed by braiding conductive resin fibers into a net-like shape, and the shield shell 27 made of conductive resin composition are welded as shown in FIG. 2, and, are connected and fixed by a connecting portion 28 formed between the braid 26 and the outer peripheral surface of the shield shell 27. Therefore, it is not necessary to perform a crimping operation with a shield ring or the like at the portion where the braid 26 and the shield shell 27 overlap, and the number of components and the operating man-hours related to the manufacture of the wire harness 11 can be reduced. That is, the manufacturing cost related to the manufacture of the wire harness 11 can be reduced and the operability in the manufacture of the wire harness 11 can be improved.

Then, the connection and fixation of the end part 33 of the protective member 20 and the braid 26 is described.

The other end of the braid 26 is formed to be connected and fixed to the end part 33 of the protective member 20. The connection and fixation of the protective member 20 and the braid 26 may be performed by, for example, welding, adhering or soldering the connecting points of the protective member 20 and the braid 26. As an example of the connection with the welding, the end part 33 of the protective member 20 and the braid 26, which is formed by braiding conductive resin fibers into a net-like shape, are welded as shown in FIG. 2, and are connected and fixed by a connecting portion 29 formed between the braid 26 and the outside surface 34 of the end part 33 of the protective member 20. Therefore, it is not necessary to performing a crimping operation with a crimp ring or the like at the portion where the end part 33 of the protective member 20 and the braid 26 overlap, and the number of components and the operating man-hours related to the manufacture of the wire harness 11 can be reduced. That is, the manufacturing cost related to the manufacture of the wire harness 11 can be reduced and the operability in the manufacture of the wire harness 11 can be improved.

As described above with reference to FIGS. 1 to 3, according to the first embodiment of the present invention, the wire harness 11 is provided with the protective member 20 which is formed of resin composition that has conductivity and is lighter than a metal pipe. Thus, an effect is achieved that it is possible to provide the wire harness 11 so that while an electromagnetic shielding effect is ensured, the wire harness 11 can be lighter in weight and the vehicle can be lighter in weight.

### Second Embodiment

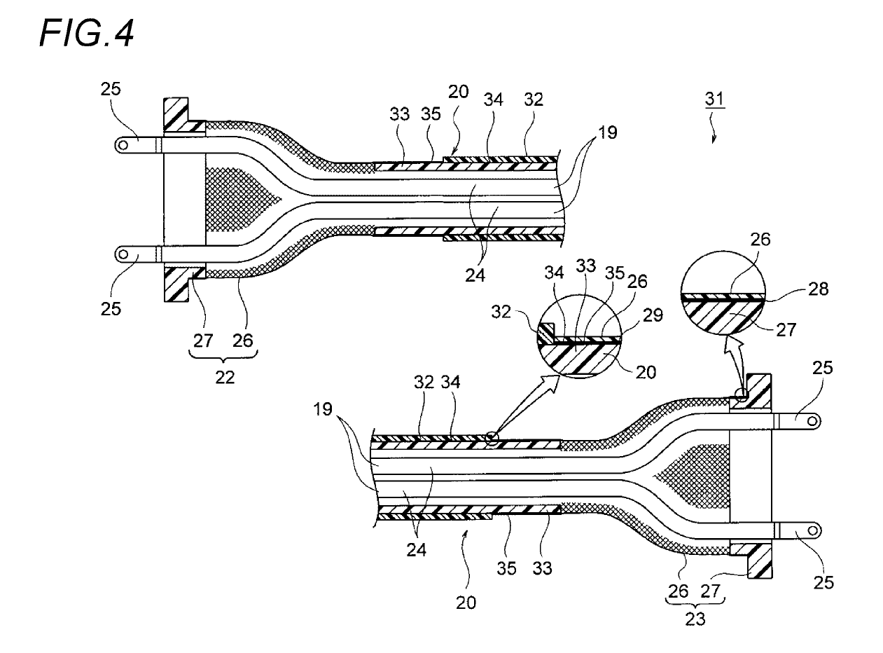

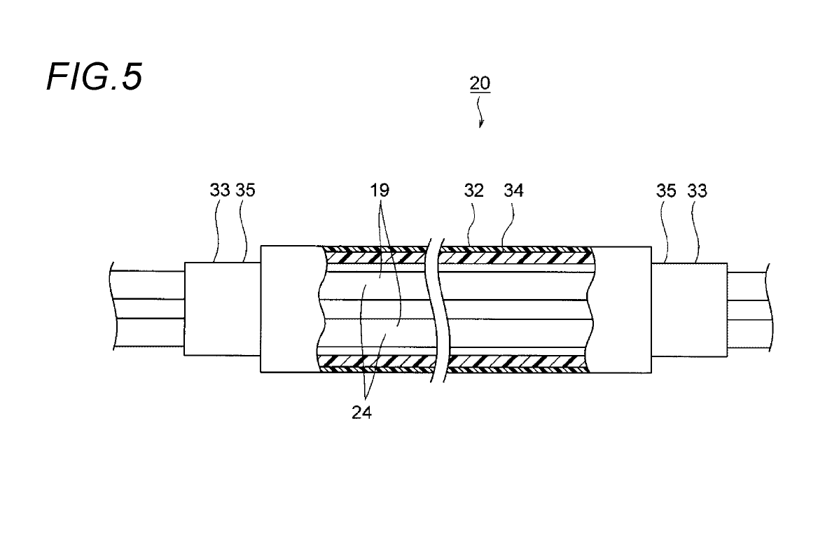

Next, a second embodiment is described with reference to the figures. FIG. 4 is a cross-sectional view which shows a construction of a wire harness. FIG. 5 is a cross-sectional view which shows a construction of a protective member.

The second embodiment is the same as the first embodiment except that an insulating resin coating 32 to be described below is provided on the outside surface 34 of the protective member 20 of the wire harness 11 in the first embodiment. Thus, the insulating resin coating 32 is described as follows.

In FIGS. 4 and 5, in the second embodiment, the insulating resin coating 32 is further formed on the outside surface 34 of the protective member 20 of the wire harness 31. The insulating resin coating 32 is formed as a layer which corresponds to the upper layer of the protective member 20, and which is made of resin composition having the property of insulating. The insulating resin coating 32 is formed by overmolding the resin having the property of insulating on the outside surface 34 of the protective member 20 after the protective member 20 is molded. In other words, the protective member 20 is formed to have a structure of two layers made of a first layer and a second layer in the second embodiment. The protective member 20 is equivalent to the first layer, and the insulating resin coating 32 formed as the upper layer of the protective member 20 is equivalent to the second layer.

By forming the insulating resin coating 32 on the outside surface 34 of the protective member 20 according to the present embodiment, while the wire harness 31 is protected from an external force such as an impact, the wiring path of the wire harness 31 can be regulated by the insulating resin coating 32 without providing, for example, an exterior member such as a protector outside the protective member 20.

As shown in FIG. 5, in the present embodiment, the insulating resin coating 32 is not formed on the outside surface 34 of the protective member 20 at areas of end parts 33 of the protective member 20, but the outside surface 34 at the end parts 33 of the protective member 20 is exposed. The outside surface 34 at the end parts 33, which is exposed, of the protective member 20, is formed as shielding member connecting parts 35.

In FIG. 4, the other ends of the braids 26, which are members constructing the terminal shielding members 22 and 23 and one end of each of which is connected to the outer peripheral surface of the shield shell 27, are connected to the shielding member connecting parts 35 of the protective member 20, respectively. The connection of the braids 26 and the shielding member connecting parts 35 shall be performed with welding in the present embodiment. This shall be an example. The braids 26 and the shielding member connecting parts 35 are connected and fixed by connecting portions 29 formed between the braids 26 and the shielding member connecting parts 35. Like the first embodiment, a braid formed by braiding conductive resin fibers into a net-like shape and a shield shell formed of conductive resin composition may be used as the braid 26 and the shield shell 27 in the present embodiment. This shall be an example.

In the embodiment, the terminal shielding members 22 and 23 can be connected and fixed to the shielding member connecting parts 35 of the protective member 20 with welding beforehand, welding, adhering, soldering or the like. Thus, because the terminal shielding members 22 and 23 can be formed integrally with the protective member 20 as one member, the number of components and the operating man-hours related to the manufacture of the wire harness 31 can be reduced. Thus, the manufacturing cost related to the manufacture of the wire harness 31 can be reduced and the operability in the manufacture of the wire harness 31 can be improved.

As described above with reference to FIGS. 1 to 5, according to the embodiments of the present invention, the wire harnesses 11 and 31 are provided with the protective member 20 which is formed of resin composition that has conductivity. Thus, besides the effect that while an electromagnetic shielding effect is ensured, the wire harnesses 11 and 31 can be lighter in weight and the vehicle can be lighter in weight, the following effects are achieved.

According to the second embodiment of the present invention, because the outside surface 34 of the protective member 20 is covered with the insulating resin coating 32, an effect is achieved that a protection function in the wire harness 31 can be improved. Further, because the wiring path of the wire harness 31 can be regulated by the insulating resin coating 32, since it is not necessary to provide an exterior member such as a protector, an effect is achieved that the number of components related to the wiring path regulation of the wire harness 31 and the operating man-hours related to the assembly of the exterior member can be reduced. An effect is achieved that the wire harness 31 can be provided so that the manufacturing cost can be reduced and the operability can be improved.

Further, according to the embodiments of the present invention, because the protective member 20 has a portion which protects the wire harness 31 from an external force such as an impact, and portions which connect shielding members such as the braids 26, an effect is achieved that while a protection function is secured, the portions connecting to the shielding members at the end parts 33 of the protective member 20 can be secured.

In addition, it is apparent that various modifications can be made to the invention without changing the purpose of the invention.

The present invention is useful because the wire harness includes a protective member that accommodates the one or more conducting paths in the protective member is formed of resin composition that has conductivity, thereby an entire of vehicle in which the wire harness is mounted can be light and an electromagnetic shielding effect can be also secured.

What is claimed is:

1. A wire harness, comprising:
one or more conducting paths;
a protective member that is formed in a pipe shape, and accommodates the one or more conducting paths in the protective member to shield a electromagnetic wave emitted from the one or more conducting paths, wherein the protective member is formed of resin composition that has conductivity;
an insulating resin coating that is formed of resin composition having a property of insulating, wherein an outside surface of the protective member is covered with the insulating resin coating; and
a braid that is connected and fixed to an end part of the protective member, wherein
an outside surface of an end part of the protective member is exposed for a predetermined range, and the exposed part is formed as a shielding member connecting part to be connected to a shield member.

2. The wire harness according to claim 1, wherein
the braid is connected and fixed to each of both ends of the protective member, and
the protective member is extended along an entire length between the both ends connected and fixed to the braids.
